(19) United States
(12) Patent Application Publication
(10) Pub. No.: US 2013/0068276 A1
(43) Pub. Date: Mar. 21, 2013

(54) SOLAR BATTERY MODULE AND MANUFACTURING METHOD THEREOF

(71) Applicants: Shih-Wei Lee, Kaohsiung City (TW); Yao-Tsang Tsai, Tainan City (TW); Ming-Hung Lin, Pingtung County (TW)

(72) Inventors: Shih-Wei Lee, Kaohsiung City (TW); Yao-Tsang Tsai, Tainan City (TW); Ming-Hung Lin, Pingtung County (TW)

(73) Assignee: AXUNTEK SOLAR ENERGY, Pingtung County (TW)

(21) Appl. No.: 13/449,323

(22) Filed: Apr. 18, 2012

(30) Foreign Application Priority Data
Sep. 16, 2011 (TW) 100133427

(51) Int. Cl. H01L 31/042; H01L 31/18

(52) U.S. Cl. 136/244; 438/57; 257/E31.124

(57) ABSTRACT

A solar battery module includes a substrate, a plurality of first striped electrodes separately formed on the substrate, a plurality of striped photoelectric transducing layers respectively formed on the corresponding first striped electrode and the substrate wherein parts of the first striped electrode are exposed, a plurality of second striped electrodes respectively formed on the corresponding striped photoelectric transducing layer, and a plurality of conductive layers respectively formed on a side of the corresponding second striped electrode and the first striped electrode adjacent to the side, and not contacting the other second striped electrode.

### BACKGROUND OF THE INVENTION

1. Field of the Invention

The present invention relates to a solar battery module and a manufacturing method thereof, and more particularly, to a solar battery module having small inactive area for preferable photoelectric transducing efficiency and a manufacturing method thereof.

2. Description of the Prior Art

A conventional solar battery module is manufactured by several cutting procedures, at least three cutting procedures, for removing the first electrode, the photoelectric transducing layer and the second electrode, so as to form the solar battery module having a plurality of battery units in a series connection. Areas on the solar battery module for the cutting procedure can not execute photoelectric transducing function, and are named inactive area. A width of the inactive area on the conventional solar battery module is about 0.5 mm, and the photoelectric transducing efficiency of the solar battery module is decreased due to dimensions of the inactive areas. For example, a manufacturing method of a solar battery module is disclosed in U.S. Pat. No. 6,080,928. The manufacturing method utilizes three cutting procedures to respectively remove the first electrode, the photoelectric transducing layer and the second electrode. The manufacturing method further forms the conductive layer between the adjacent solar battery units for connecting the first electrode and the second electrode between the solar battery units to form the series connection.

However, the conventional manufacturing method executes the cutting procedure after the conductive layer is formed, so as to remove a part of the second electrode between the adjacent conductive layers, and to prevent the conductive layer from simultaneously contacting the first electrode and the second electrode of the same battery unit (which means prevents the battery unit from short). Therefore, the procedures of the conventional manufacturing method are complicated and spend labor hours. The related conventional solar battery module has large inactive area, and photoelectric transducing efficiency of the solar battery module can not be increased effectively and stably.

### SUMMARY OF THE INVENTION

The present invention provides a solar battery module having small inactive area for preferable photoelectric transducing efficiency and a manufacturing method thereof for solving above drawbacks.

According to the claimed invention, a solar battery module includes a substrate, a plurality of first striped electrodes, a plurality of striped photoelectric transducing layers, a plurality of second striped electrodes, and a plurality of conductive layers. The first striped electrodes are separately formed on the substrate along a first direction. Each striped photoelectric transducing layer is formed between the adjacent first striped electrodes and on the substrate. A part of the corresponding first striped electrode is exposed between the adjacent striped photoelectric transducing layers. Each second striped electrode is formed on the corresponding striped photoelectric transducing layer along the first direction. Each conductive layer is formed on a side of the corresponding second striped electrode and on the first striped electrode adjacent to the side along the first direction, and does not contact the other second striped electrode adjacent to the side.

According to the claimed invention, the part of the corresponding first striped electrode and a part of the substrate are exposed between the adjacent striped photoelectric transducing layers.

According to the claimed invention, each conductive layer is formed on the side of the corresponding second striped electrode, the first striped electrode adjacent to the side, and the part of the substrate along the first direction.

According to the claimed invention, a width of the second striped electrode is substantially equal to a width of the striped photoelectric transducing layer.

According to the claimed invention, the solar battery module further includes a buffer layer formed between the striped photoelectric transducing layer and the second striped electrode.

According to the claimed invention, the first striped electrode is made of metal material.

According to the claimed invention, the striped photoelectric transducing layer is made of copper indium selenide material.

According to the claimed invention, the second striped electrode is made of aluminum zinc oxide material or tin-doped indium oxide material.

According to the claimed invention, the conductive layer is made by a jet printing method.

According to the claimed invention, a width of the conductive layer is substantially between 40˜60 um.

According to the claimed invention, a width of the exposed part of the first striped electrode between the adjacent striped photoelectric transducing layers is substantially between 50˜100 um.

According to the claimed invention, a manufacturing method for a solar battery module includes forming a first electrode on a substrate; removing a part of the first electrode along a first direction to form a plurality of first striped electrodes separately on the substrate; forming a photoelectric transducing layer on the first striped electrodes and the substrate; forming a second electrode on the photoelectric transducing layer; removing a part of the second electrode and a part of the photoelectric transducing layer along the first direction so as to expose parts of the first striped electrodes and to form a plurality of striped photoelectric transducing layers and a plurality of second striped electrodes; and forming a plurality of conductive layers respectively on a side of the corresponding second striped electrode and on the first striped electrode adjacent to the side along the first direction, and not contacting the other second striped electrode adjacent to the side.

According to the claimed invention, the manufacturing method further includes removing the part of the second electrode and the part of the photoelectric transducing layer along the first direction so as to expose the parts of the first striped electrodes and a part of the substrate and to form the plurality of striped photoelectric transducing layers and the plurality of second striped electrodes.

According to the claimed invention, the manufacturing method further includes forming the plurality of conductive layers respectively on the side of the corresponding second striped electrode, on the first striped electrode adjacent to the side, and on the exposed part of the substrate along the first direction.

The solar battery module and the related manufacturing method of the present invention can economize the machine cost, increase the speed of the procedures, and reduce the proportion of the inactive area to the panel dimension of the solar battery module, so as to enhance the photoelectric transducing efficiency of the solar battery module.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a solar battery module according to a first embodiment of the present invention.

FIG. 2 is a diagram of a solar battery module according to a second embodiment of the present invention.

FIG. 3 is a flow chart of manufacturing the solar battery module according to the first embodiment of the present invention.

FIG. 4 to FIG. 8A respectively are sectional views of the solar battery module along a second direction in different procedures according to the first embodiment of the present invention.

FIG. 4 to FIG. 6, FIG. 7B and FIG. 8B respectively are sectional views of the solar battery module along the second direction in different procedures according to the second embodiment of the present invention.

FIG. 9 is a flow chart of manufacturing the solar battery module according to the second embodiment of the present invention.

### DETAILED DESCRIPTION

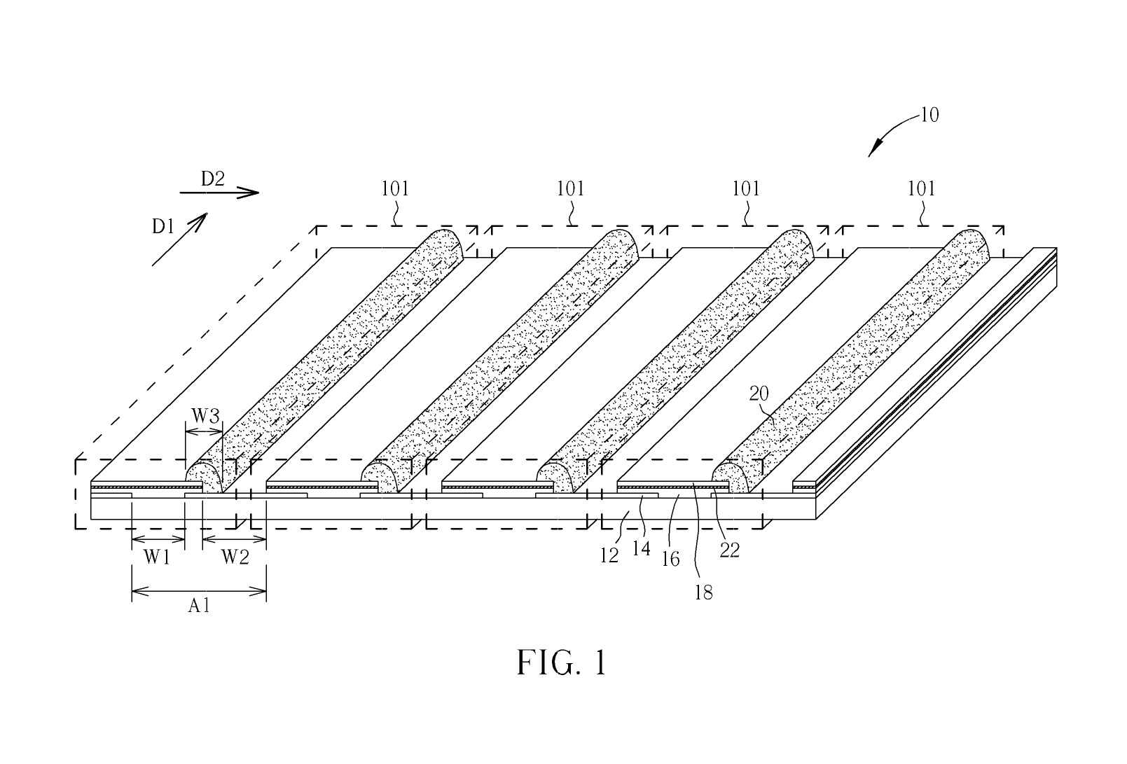

Please refer to FIG. 1. FIG. 1 is a diagram of a solar battery module 10 according to a first embodiment of the present invention. The solar battery module 10 includes a substrate 12, a plurality of first striped electrodes 14, a plurality of striped photoelectric transducing layers 16, a plurality of second striped electrodes 18 and a plurality of conductive layers 20. As shown in FIG. 1, the plurality of first striped electrodes 14 can be respectively and separately formed on the substrate 12 along a first direction D1. A width W1 of an exposed part of the substrate 12 between the adjacent first striped electrodes 14 can be substantially about 50 um. Each striped photoelectric transducing layer 16 can be formed between the adjacent first striped electrodes 14 and on the substrate 12 along the first direction D1, and a part of the first striped electrode 14 can be exposed between the adjacent striped photoelectric transducing layers 16.

Generally, a width W2 of the exposed part of the first striped electrode 14 can be substantially between 50˜100 um. Each second striped electrode 18 can be formed on the corresponding striped photoelectric transducing layer 16 along the first direction D1, and a width of the second striped electrode 18 can be substantially equal to a width of the striped photoelectric transducing layer 16. Each conductive layer 20 can be formed on a side of the corresponding second striped electrode 18 and on the first striped electrode 14 adjacent to the side along the first direction D1, and does not contact the other second striped electrode 18 adjacent to the side. Therefore, each second striped electrode 18 can be connected to the adjacent first striped electrode 14 along a second direction D2 different from the first direction D1 to form a series connection. A width W3 of the conductive layer 20 can be substantially between 40˜60 um, and a width of an inactive area on the solar battery module 10 of the first embodiment can be A1 shown in FIG. 1.

The solar battery module 10 is composed of a plurality of solar batteries 101. The striped photoelectric transducing layer 16 of each solar battery 101 can receive optical energy and transform the optical energy into electric power. The first striped electrode 14 and the second striped electrode 18 of each solar battery 101 can respectively be a positive electrode and a negative electrode for outputting the electric power, so the plurality of solar batteries 101 can utilize the plurality of conductive layers 20 to form the series connection along the second direction D2, and an output voltage of the solar battery module 10 can be easily adjusted according to user's demand. In addition, the solar battery module 10 can further include a buffer layer 22 disposed between the striped photoelectric transducing layer 16 and the second striped electrode 18.

Generally, the substrate 12 can be the soda-lime glass or the flexible base. The first striped electrode 14 can be a metal electrode made of molybdenum (Mo), tantalum (Ta), titanium (Ti), vanadium (V) or zirconium material. The striped photoelectric transducing layer 16 can be a chalcopyrite structure, such as copper indium diselenide, copper indium sulfur, copper indium gallium selenide, or copper indium gallium selenide sulfur. The second striped electrode 18 can be made of aluminum-doped zinc oxide (AZO) material or indium tin oxide (ITO) material. The conductive layer 20 can be the conductive silver paste or the conductive aluminum paste. The buffer layer 22 can be made of zinc sulphide (ZnS) material, cadmium sulfide (CdS), indium (II) sulfide (InS) and intrinsic zinc oxide (ZnO) material. Material of the substrate 12, the first striped electrode 14, the striped photoelectric transducing layer 16, the second striped electrode 18 and the buffer layer 22 are not limited to the above-mentioned embodiment, and depend on design demand.

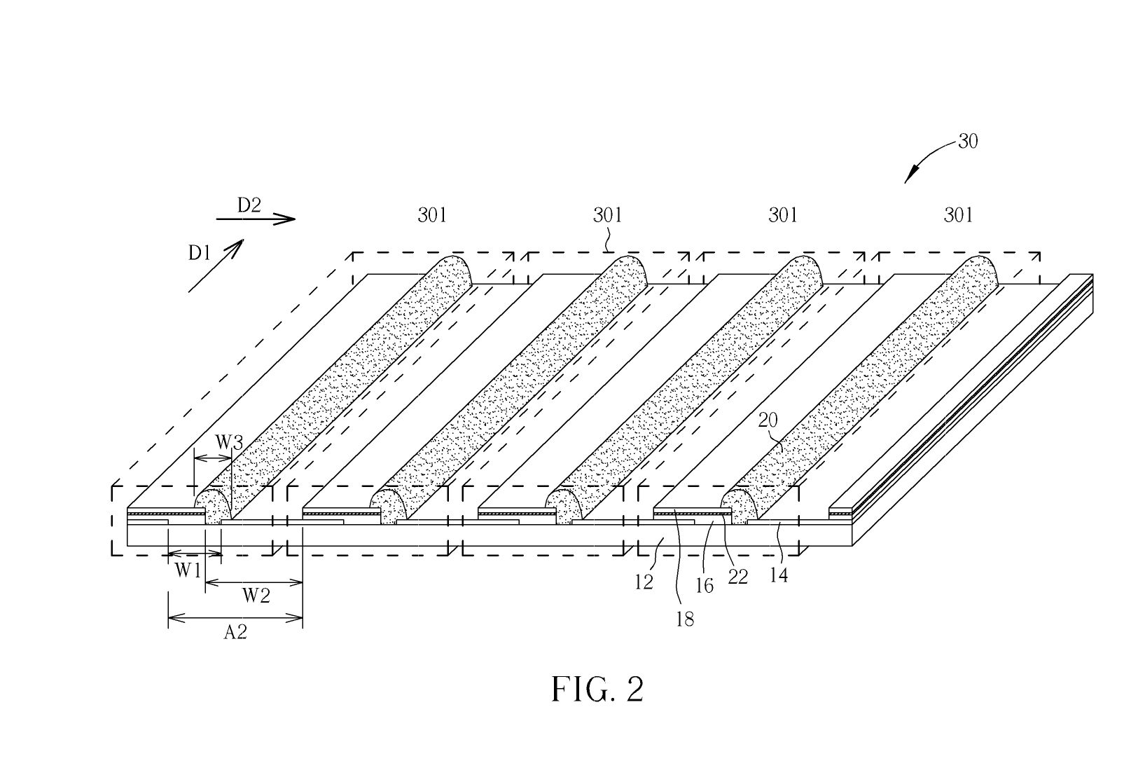

Please refer to FIG. 2. FIG. 2 is a diagram of a solar battery module 30 according to a second embodiment of the present invention. In the second embodiment, elements having the same numerals as ones of the first embodiment have the same material and the same function, and detail description is omitted herein for simplicity. Difference between the second embodiment and the first embodiment is that the part of the first striped electrode 14 and a part of the substrate 12 can be exposed between the adjacent photoelectric transducing layers 16 of the solar battery module 30, as shown in

FIG. 2. Each conductive layer 20 can be formed on the side of the corresponding second striped electrode 18 and on the first striped electrode 14 adjacent to the side, but does not contact the other second striped electrode 18 adjacent to the side. Comparing to the first embodiment, a width of the inactive area on the solar battery module 30 of the second embodiment can be A2 shown in FIG. 2, and the area A2 is substantially smaller than the area A1.

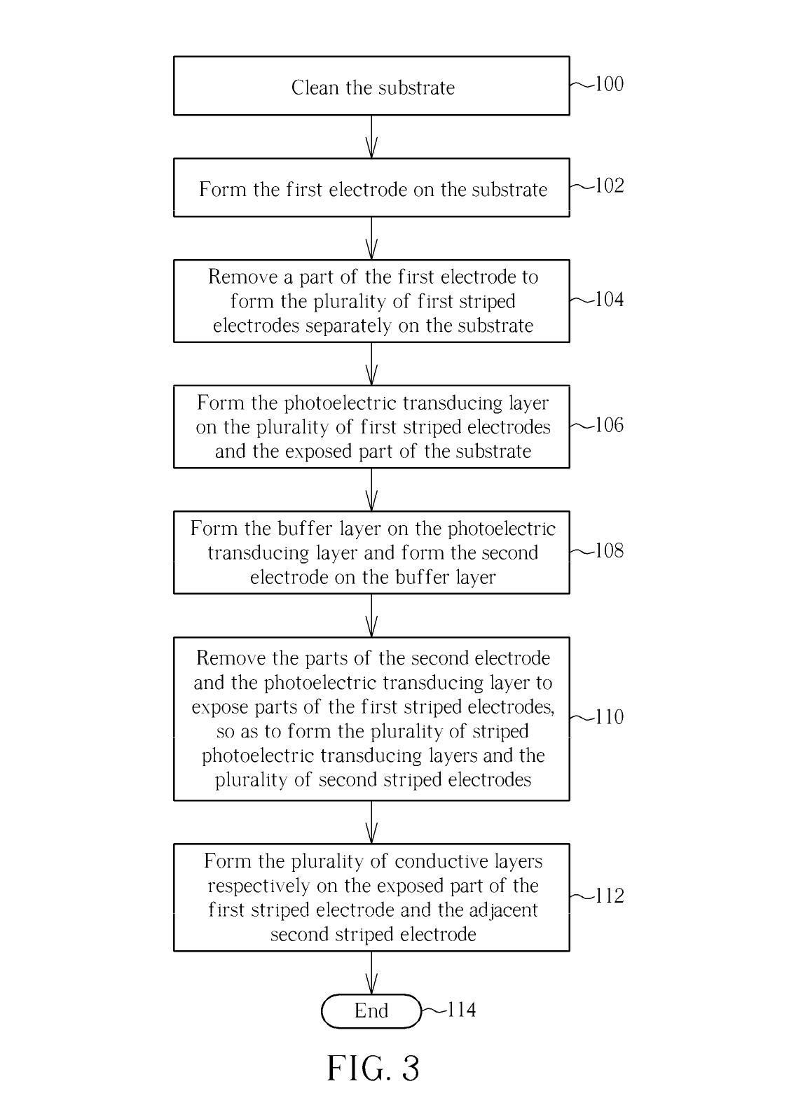

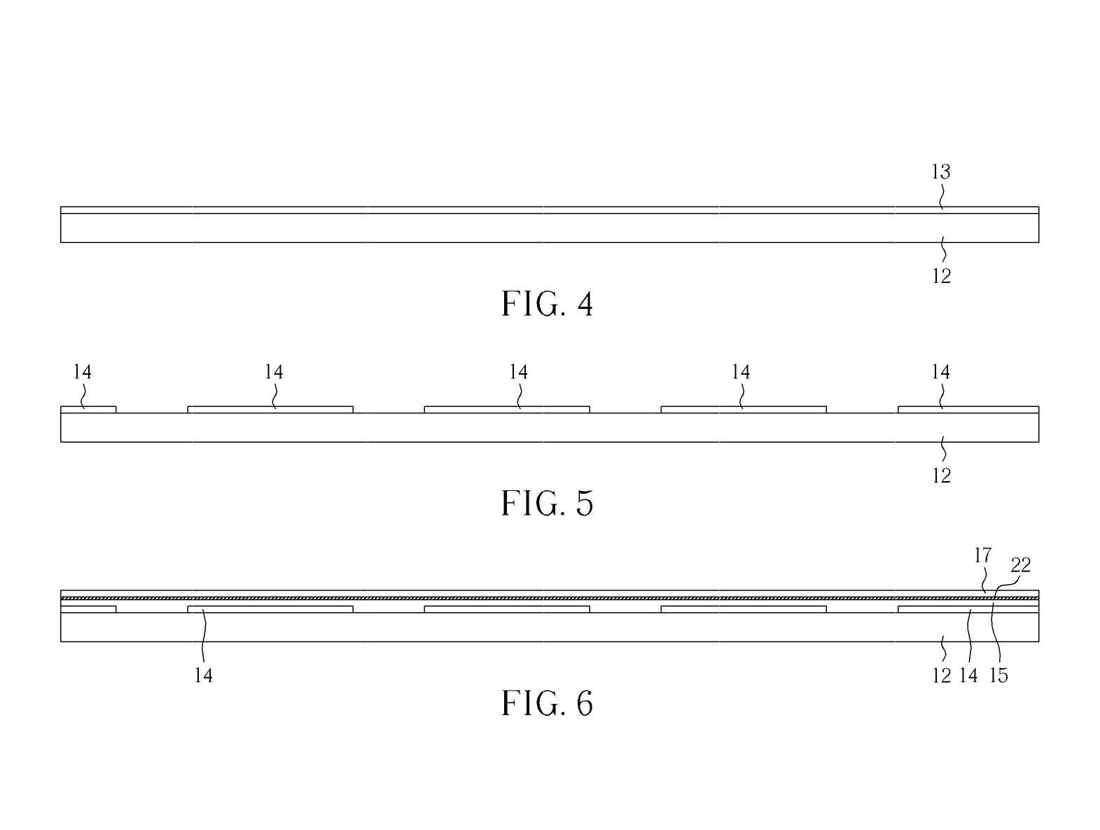

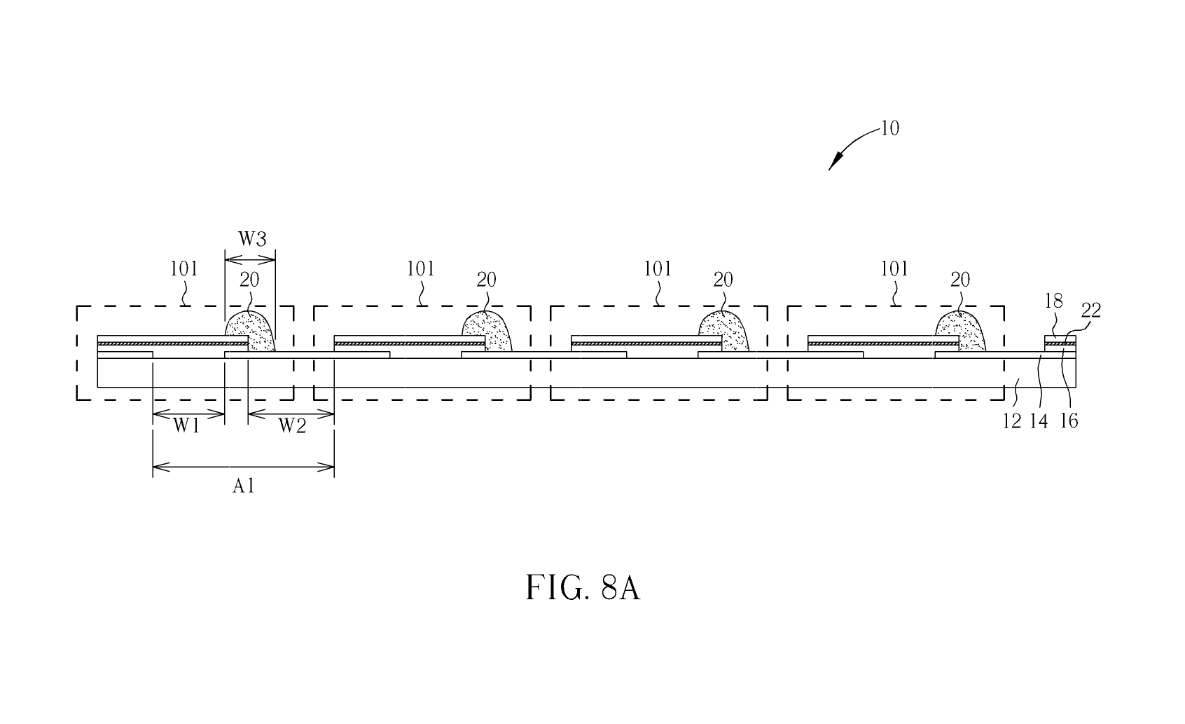

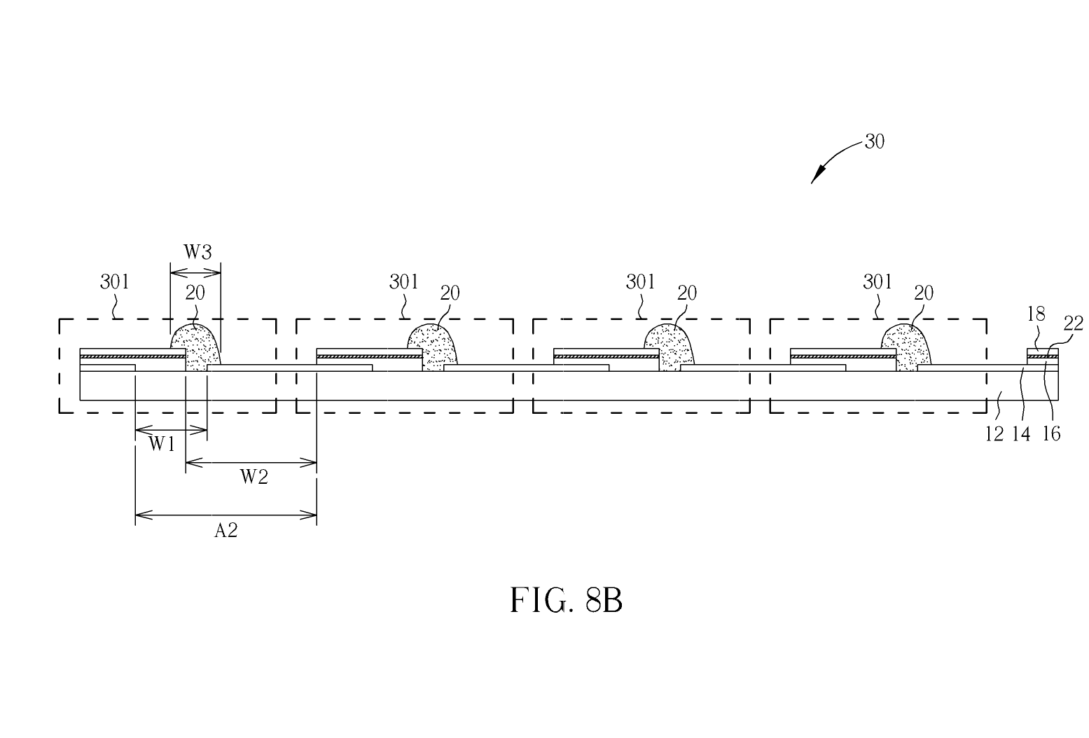

Please refer to FIG. 1, FIG. 3 to FIG. 6, FIG. 7A and FIG. 8A. FIG. 3 is a flow chart of manufacturing the solar battery module 10 according to the first embodiment of the present invention. FIG. 4 to FIG. 8A respectively are sectional views of the solar battery module 10 along the second direction D2 in different procedures according to the first embodiment of the present invention. The manufacturing method includes following steps:

Step 100: Clean the substrate 12.

Step 102: Form a first electrode 13 on the substrate 12.

Step 104: Remove a part of the first electrode 13 along the first direction D1 so as to form the plurality of first striped electrodes 14 separately on the substrate 12.

Step 106: Form a photoelectric transducing layer 15 on the plurality of first striped electrodes 14 and the exposed part of the substrate 12.

Step 108: Form the buffer layer 22 on the photoelectric transducing layer 15, and form a second electrode 17 on the buffer layer 22.

Step 110: Remove a part of the second electrode 17 and a part of the photoelectric transducing layer 15 (and a part of the buffer layer 22) along the first direction D1 simultaneously, so as to expose parts of the first striped electrodes 14, and to form the plurality of striped photoelectric transducing layers 16 and the plurality of second striped electrodes 18.

Step 112: Form the plurality of conductive layers 20 respectively on the exposed part of the first striped electrode 14 and the adjacent second striped electrode 18 along the first direction D1, so that the first striped electrode 14 and the second striped electrode 18 of each solar battery 101 can form the series connection along the second direction D2 via the conductive layers 20.

Step 114: End.

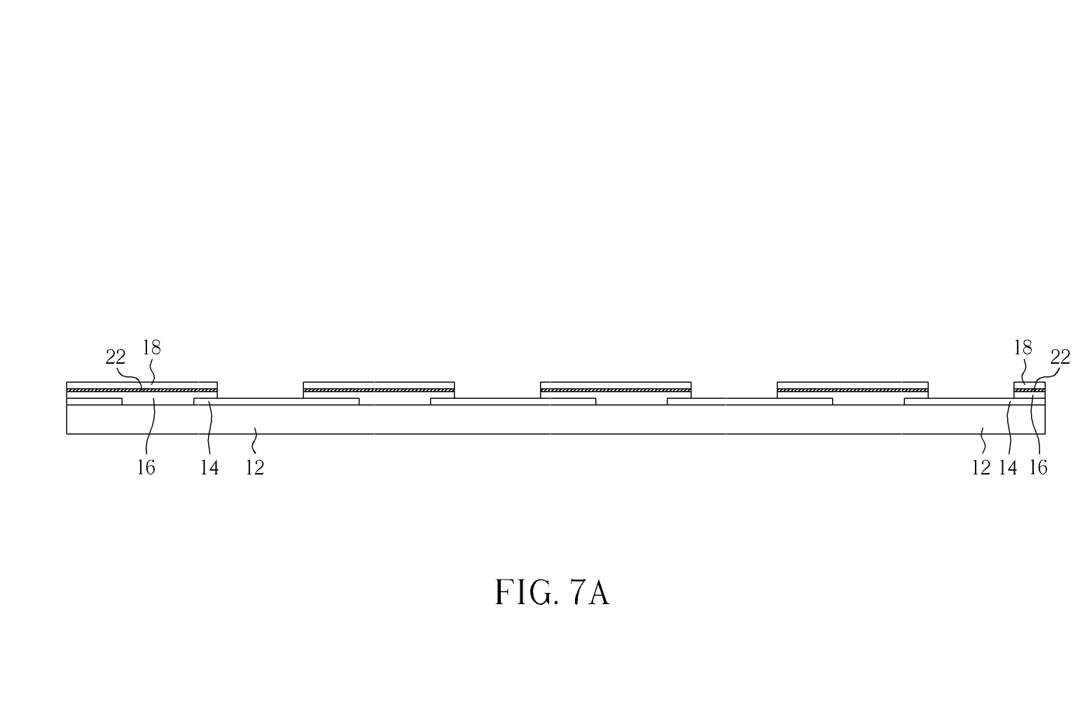

Detail description of above-mentioned steps is introduced as following. Step 100 to step 112 respectively corresponds to FIG. 4 to FIG. 8A. First, the substrate 12 is cleaned for preventing dirt from heaping on the substrate 12. The substrate 12 can be made of glass material, soft metal base, and materials applied to copper indium selenide solar battery module. At this time, a barrier layer made of Al2O3 or SiO2 material can be selectively formed on the substrate 12 for isolating impurity of the substrate 12 from diffusing to the photoelectric transducing layer 16. Further, NaF material can be formed on the substrate 12 by evaporation method for crystallizing the CIGS material on the substrate 12. Then, as shown in FIG. 4 (step 100 and step 102) and FIG. 5 (step 104), the first electrode 13 made of Mo material can be formed on the substrate 12 by sputtering or other technology, and the parts of the first electrode 13 can be removed along the first direction D1 by laser technology or other removing technology, so as to expose the part of the substrate 12 and to form the plurality of first striped electrodes 14 separately on the substrate 12.

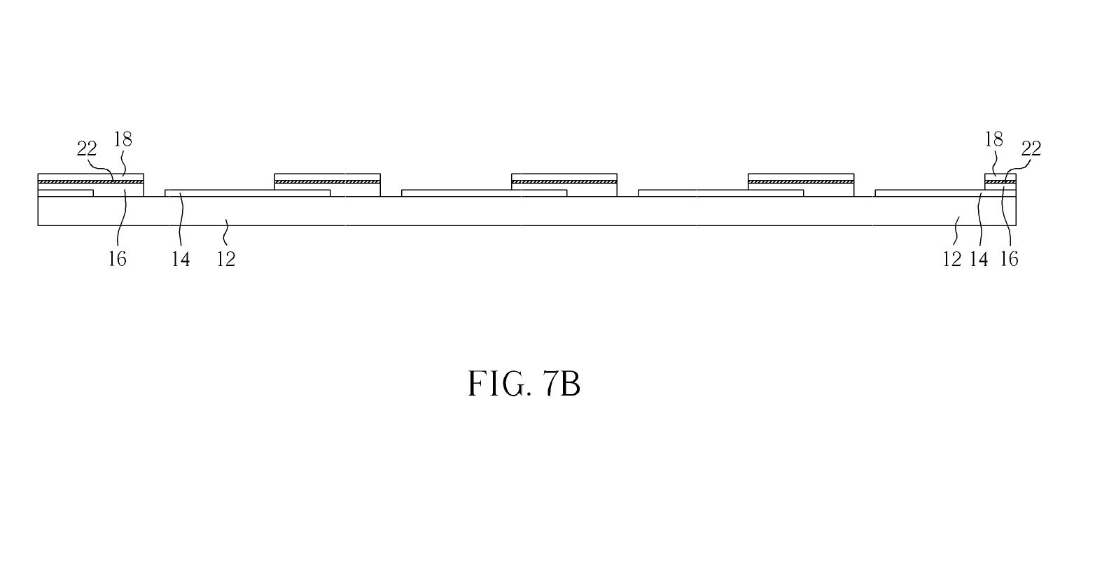

As shown in FIG. 6 (step 106 and step 108), the photoelectric transducing layer 15 can be formed on the plurality of first striped electrodes 14 and the exposed part of the substrate 12, the buffer layer 22 made of the ZnS material and the intrinsic ZnO material can be formed on the photoelectric transducing layer 15, and the second electrode 17 can be formed on the buffer layer 22 in sequence by thin film deposition method or other technology. Then as shown in FIG. 7 (step 110), the part of the second electrode 17, the part of the photoelectric transducing layer 15 and the part of the buffer layer 22 can be simultaneously removed along the first direction D1 by a scraper or other technology, so as to expose the part of the first striped electrode 14, and to separately form the plurality of second striped electrodes 18 and the plurality of striped photoelectric transducing layers 16.

Because the second electrode 17 and the photoelectric transducing layer 15 are removed simultaneously in step 110, the width of each second striped electrode 18 can be substantially equal to the width of each striped photoelectric transducing layer 16. The intrinsic ZnO material is a film having preferable photoelectric property for increasing photoelectric transducing efficiency and electricity generating efficiency of the solar battery module 10. Generally, the thin film deposition could be realized by co-evaporation, vacuum sputter, and selenization methods to achieve preferable photoelectric transducing efficiency of the CIGS film. In addition, material and procedure sequence of the buffer layer 22 are not limited to the above-mentioned embodiment, which can be formed selectively, and depend on design demand.

Final, as shown in FIG. 8A (step 112), the plurality of conductive layers 20 can be respectively formed on the exposed part of the first striped electrode 14 and the adjacent second striped electrode 18 along the first direction D1 by the jet printing method. A width of each conductive layer 20 can be substantially between 40˜60 um for connecting the second striped electrode 18 of the solar battery 101 to the first striped electrode 14 of the adjacent solar battery 101, so that the plurality of solar batteries 101 can form the series connection along the second direction D2. The jet printing method can form the minimum width of the conductive layer 20 about 40 um, to ensure that the conductive layer 20 does not simultaneously contact the first striped electrode 14 and the second striped electrode 18 of the same solar battery 101 for preventing the short. Therefore, the width of the inactive area on the solar battery module 10 of the first embodiment can be the area A1 shown in FIG. 8A, and the area A1 can be substantially smaller than 250 um.

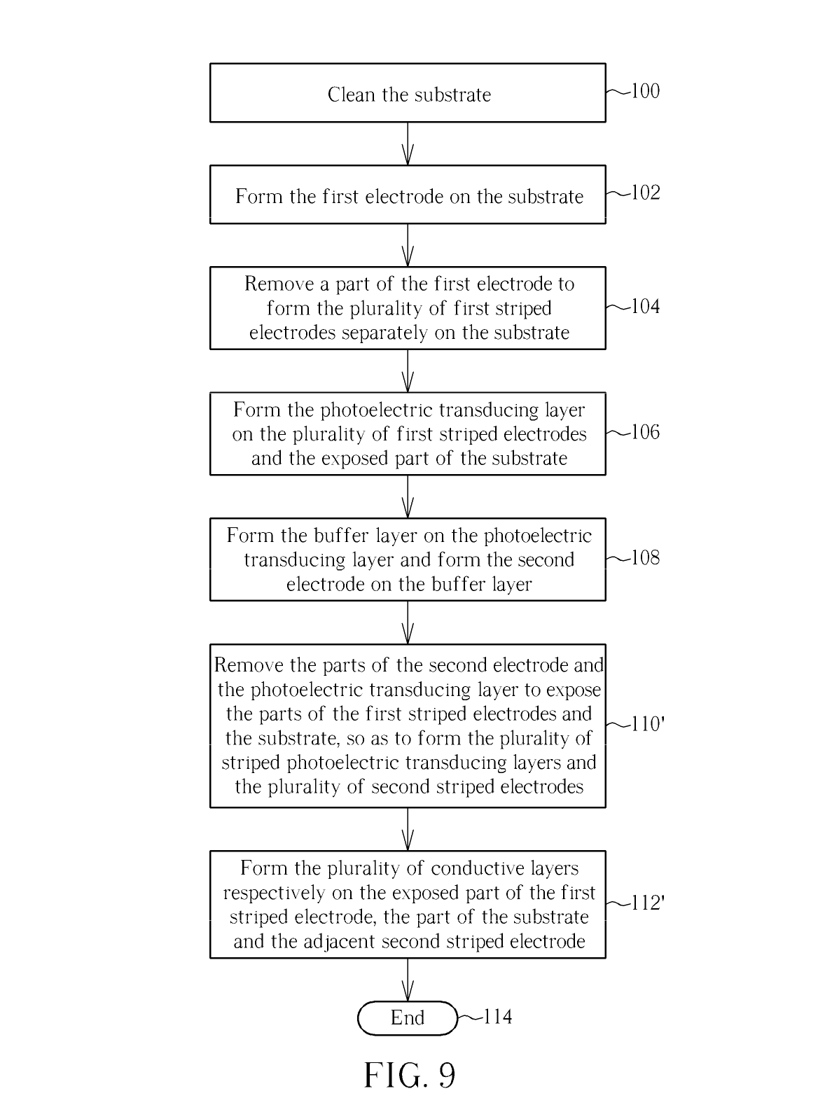

Please refer to FIG. 9. FIG. 9 is a flow chart of manufacturing the solar battery module 30 according to the second embodiment of the present invention. FIG. 4 to FIG. 6, FIG. 7B and FIG. 8B respectively are sectional views of the solar battery module 30 along the second direction D2 in different procedures according to the second embodiment of the present invention. The method includes following steps:

Step 100: Clean the substrate 12.

Step 102: Form the first electrode 13 on the substrate 12.

Step 104: Remove the part of the first electrode 13 along the first direction D1 so as to form the plurality of first striped electrodes 14 separately on the substrate 12.

Step 106: Form the photoelectric transducing layer 15 on the plurality of first striped electrodes 14 and the exposed part of the substrate 12.

Step 108: Form the buffer layer 22 on the photoelectric transducing layer 15, and form the second electrode 17 on the buffer layer 22.

Step 110′: Remove the part of the second electrode 17 and the part of the photoelectric transducing layer 15 (and the part of the buffer layer 22) along the first direction D1 simultaneously, so as to expose the parts of the first striped electrodes 14 and the part of the substrate 12, and to form the plurality of striped photoelectric transducing layers 16 and the plurality of second striped electrodes 18.

Step 112′: Form the plurality of conductive layers 20 respectively on the exposed part of the first striped electrode 14, the part of the substrate 12 and the adjacent second striped electrode 18 along the first direction D1, so that the first striped electrode 14 and the second striped electrode 18 of each solar battery 301 can form the series connection along the second direction D2 via the conductive layers 20.

Step 114: End.

Detail description of above-mentioned steps is introduced as following. Step 100 to step 112′ respectively corresponds to FIG. 4 to FIG. 8B. Step 100 to step 108 (which means from FIG. 4 to FIG. 6) of the second embodiment are the same as ones of the first embodiment, and detail description is omitted herein for simplicity. Difference between the second embodiment and the first embodiment is that the part of the second electrode 17 and the part of the photoelectric transducing layer 15 (and the part of the buffer layer 22) can be simultaneously removed along the first direction D1 by the scraper or other technology, shown in FIG. 7B (step 110′), so as to expose the part of the first striped electrode 14 and the part of the substrate 12. Thus, an area with the width W1 can partly overlap an area with the width W2.

As shown in FIG. 8B (step 112′), the plurality of conductive layers 20 can be respectively formed on the exposed part of the first striped electrode 14, the part of the substrate 12 and the adjacent second striped electrode 18 along the first direction D1 by the jet printing method, so as to electrically connect the adjacent solar batteries 301. Method and dimension of the conductive layer 20 of the second embodiment are the same as ones of the first embodiment, and detail description is omitted herein for simplicity. Comparing the first embodiment, the width of the inactive area on the solar battery module 30 of the second embodiment can be the area A2 shown in FIG. 8B. The area A2 can be substantially smaller than 250 um, so the area A2 can be smaller than the area A1.

In conclusion, the solar battery module of the present invention can form the photoelectric transducing layer, the buffer layer and the second electrode respectively on the first striped electrodes and the substrate in sequence, and then simultaneously remove the part of the photoelectric transducing layer, the part of the buffer and the part of the second electrode with the same width, so as to from the plurality of solar batteries separately on the substrate. The present invention can further form the conductive layer on the corresponding first striped electrode and the second striped electrode, so that each conductive layer can be utilized to electrically connect the adjacent solar batteries for forming the series connection. Therefore, the manufacturing method of the present invention can use one machine to execute procedures of the buffer layer and the second electrode, so as to economize the manufacturing cost and the labor hours effectively.

In addition, the manufacturing method of the present invention could merely include two cutting procedures. One of the cutting procedures can remove the first electrode to form the plurality of first striped electrodes, and another cutting procedure can simultaneously remove the photoelectric transducing layer and the second electrode to form the plurality of striped photoelectric transducing layers and the plurality of second striped electrodes. Because the cutting area on the solar battery module can not execute the photoelectric transducing function, so that the present invention can increase speed of the manufacturing method by less cutting procedures (the prior art includes three cutting procedures), and can decrease a proportion of the inactive area to panel dimension of the solar battery module, so that the solar battery module of the present invention can have preferable photoelectric transducing efficiency.

Comparing to the prior art, the solar battery module and the related manufacturing method of the present invention can economize the machine cost, increase the speed of the procedures, and reduce the proportion of the useless area to the panel dimension of the solar battery module, so as to enhance the photoelectric transducing efficiency of the solar battery module.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar battery module comprising:
a substrate;
a plurality of first striped electrodes separately formed on the substrate along a first direction;
a plurality of striped photoelectric transducing layers, each striped photoelectric transducing layer being formed between the adjacent first striped electrodes and on the substrate, a part of the corresponding first striped electrode being exposed between the adjacent striped photoelectric transducing layers;
a plurality of second striped electrodes, each second striped electrode being formed on the corresponding striped photoelectric transducing layer along the first direction; and
a plurality of conductive layers, each conductive layer being formed on a side of the corresponding second striped electrode and on the first striped electrode adjacent to the side along the first direction, and not contacting the other second striped electrode adjacent to the side.

2. The solar battery module of claim 1, wherein the part of the corresponding first striped electrode and a part of the substrate are exposed between the adjacent striped photoelectric transducing layers.

3. The solar battery module of claim 2, wherein each conductive layer is formed on the side of the corresponding second striped electrode, the first striped electrode adjacent to the side, and the part of the substrate along the first direction.

4. The solar battery module of claim 1, wherein a width of the second striped electrode is substantially equal to a width of the striped photoelectric transducing layer.

5. The solar battery module of claim 1, further comprising:
a buffer layer formed between the striped photoelectric transducing layer and the second striped electrode.

6. The solar battery module of claim 1, wherein the first striped electrode is made of metal material.

7. The solar battery module of claim 1, wherein the striped photoelectric transducing layer is made of copper indium selenide material.

8. The solar battery module of claim 1, wherein the second striped electrode is made of aluminum zinc oxide material or tin-doped indium oxide material.

9. The solar battery module of claim 1, wherein the conductive layer is made by a jet printing method.

10. The solar battery module of claim 1, wherein a width of the conductive layer is substantially between 40˜60 um.

11. The solar battery module of claim 1, wherein a width of the exposed part of the first striped electrode between the adjacent striped photoelectric transducing layers is substantially between 50˜100 um.

12. A manufacturing method of manufacturing a solar battery module, the manufacturing method comprising:
forming a first electrode on a substrate;
removing a part of the first electrode along a first direction to form a plurality of first striped electrodes separately on the substrate;
forming a photoelectric transducing layer on the first striped electrodes and the substrate;
forming a second electrode on the photoelectric transducing layer;
removing a part of the second electrode and a part of the photoelectric transducing layer along the first direction so as to expose parts of the first striped electrodes and to form a plurality of striped photoelectric transducing layers and a plurality of second striped electrodes; and
forming a plurality of conductive layers respectively on a side of the corresponding second striped electrode and on the first striped electrode adjacent to the side along the first direction, and not contacting the other second striped electrode adjacent to the side.

13. The manufacturing method of claim 12, further comprising:
removing the part of the second electrode and the part of the photoelectric transducing layer along the first direction so as to expose the parts of the first striped electrodes and a part of the substrate and to form the plurality of striped photoelectric transducing layers and the plurality of second striped electrodes.

14. The manufacturing method of claim 13, further comprising:
forming the plurality of conductive layers respectively on the side of the corresponding second striped electrode, on the first striped electrode adjacent to the side, and on the exposed part of the substrate along the first direction.

15. The manufacturing method of claim 12, further comprising:
forming a buffer layer between the photoelectric transducing layer and the second electrode.

16. The manufacturing method of claim 12, further comprising:
removing the part of the first electrode by a laser cutting technology to form the plurality of first striped electrodes separately on the substrate.

17. The manufacturing method of claim 12, further comprising:
removing the part of the second electrode and the part of photoelectric transducing layer along the first direction simultaneously by a scraper so as to expose the parts of the first striped electrodes and to form the plurality of striped photoelectric transducing layers and the plurality of second striped electrodes.

18. The manufacturing method of claim 12, further comprising:
forming the plurality of conductive layers respectively on the side of the corresponding second striped electrode and on the first striped electrode adjacent to the side along the first direction by a jet printing method.

19. The manufacturing method of claim 12, wherein a width of the conductive layer is substantially between 40˜60 um.

20. The manufacturing method of claim 12, wherein a width of the exposed part of the first striped electrode between the adjacent striped photoelectric transducing layers is substantially between 50˜100 um.
